(19) United States
(12) Patent Application Publication
(10) Pub. No.: US 2013/0240010 A1
(43) Pub. Date: Sep. 19, 2013

(54) SOLAR CELL AND MANUFACTURING METHOD THEREOF

(71) Applicant: Yun Gi KIM, Yongin-si (KR)

(72) Inventor: Yun Gi KIM, Yongin-si (KR)

(73) Assignee: SAMSUNG ELECTRONICS CO., LTD., Suwon-si (KR)

(21) Appl. No.: 13/585,438

(22) Filed: Aug. 14, 2012

(30) Foreign Application Priority Data
Mar. 13, 2012 (KR) 1020120025759

(51) Int. Cl. H01L 31/042; H01L 31/18

(52) U.S. Cl. 136/244; 438/69; 257/E31.127

(57) ABSTRACT

According to example embodiments, a solar cell includes a transparent base substrate having a first surface and a second surface opposite the first surface, a first photoelectric layer having a thin film shape on the first surface of the base substrate; and a second photoelectric layer having a thin film shape on the second surface of the base substrate. A bandgap of the second photoelectric layer may be different than a bandgap of the first photoelectric layer.

### RELATED APPLICATIONS

This application claims priority under 35 U.S.C. §119 to Korean Patent Application No. 10-2012-0025759 filed in the Korean Intellectual Property Office on Mar. 13, 2012, the entire contents of which are incorporated herein by reference.

### BACKGROUND

1. Field

Example embodiments relate to a solar cell and/or a manufacturing method thereof.

2. Description of the Related Art

Fossil fuels, such as coal and petroleum, are used as energy sources. However, fossil fuels are being exhausted and cause global warming and environmental pollution. Solar light, tidal power, wind power, geothermal heat and the like are being studied as an alternative energy sources for replacing fossil fuel.

Among them, technology of converting solar light into electricity takes the lead. Various materials and devices are being developed for solar cells that convert solar light into electricity. Solar cells may have a multi-layered p-n junction structure and may include III-V Group materials.

The above-described technology may use specific wavelength of solar light among various wavelengths. A multi-junction structure may be applied to use several wavelengths. Techniques for using the currents generated by multi-junction solar cells are being studied.

### SUMMARY

Example embodiments relate to a solar cell and/or a manufacturing method thereof.

According to example embodiments, a solar cell includes a transparent base substrate having a first surface and a second surface opposite the first surface, a first photoelectric layer having a thin film shape on the first surface of the base substrate, and a second photoelectric layer having a thin film shape on the second surface of the base substrate. The second photoelectric layer has a different bandgap than a bandgap of the first photoelectric layer.

The first surface may be under the second surface, and the bandgap of the first photoelectric layer may be smaller than the bandgap of the second photoelectric layer.

The solar cell may further include first and second terminals connected to the first photoelectric layer, and third and fourth terminals connected to the second photoelectric layer. The first photoelectric layer may be between the base substrate and the first and second terminals. The second photoelectric layer may be between the base substrate and the third and fourth terminals.

The first photoelectric layer may include first and second impurity regions connected to the first and second terminals, respectively, and the second photoelectric layer may include third and fourth impurity regions connected to the third and fourth terminals, respectively. The first and second impurity regions may have opposite conductivities. The third and fourth impurity regions may have opposite conductivities.

The solar cell may further include a passivation layer between the substrate and the first photoelectric layer.

The solar cell may further include a wavelength conversion member between the base substrate and the first photoelectric layer. The wavelength conversion member may be configured to change a wavelength of incident light.

The wavelength conversion member may include a pattern on the substrate.

The wavelength conversion member may include nanoparticles.

The base substrate may include an insulator, for example, at least one of glass, quartz, and plastic.

The base substrate may have a thickness from about 50 microns to about 10 centimeters.

According to example embodiments, a method of manufacturing a solar cell includes forming a first photoelectric layer by thin film deposition on a first surface of a transparent insulating base substrate, forming a second photoelectric layer by thin film deposition on a second surface of the base substrate. The second photoelectric layer may have a different bandgap than a bandgap of the first photoelectric layer. The first surface and the second surface of the base substrate may be opposite to each other. The method may further include forming a first electrode on the first photoelectric layer opposite the base substrate, and forming a second electrode on the second photoelectric layer opposite the base substrate.

The first surface may be under the second surface, and the bandgap of the first photoelectric layer may be less than the bandgap of the second photoelectric layer.

The method may further include forming a plurality of impurity regions by implanting impurities in the first and second photoelectric layers.

The method may further include forming a passivation layer between the base substrate and the first photoelectric layer.

The method may further include forming a wavelength conversion member between the base substrate and the first photoelectric layer. The wavelength conversion member may be configured to change wavelength of incident light.

Forming the wavelength conversion member may include forming a pattern on the base substrate.

Forming the wavelength conversion member may include forming nanoparticles on the base substrate.

The base substrate may include at least one of glass, quartz, and plastic.

The base substrate may have a thickness from about 50 microns to about 10 centimeters.

The thin film deposition may include one of chemical deposition and physical deposition.

### BRIEF DESCRIPTION OF THE DRAWINGS

The foregoing and other features and advantages of example embodiments will be apparent from the more particular description of non-limiting embodiments of inventive concepts, as illustrated in the accompanying drawings in which like reference characters refer to the same parts throughout the different views. The drawings are not necessarily to scale, emphasis instead being placed upon illustrating the principles of example embodiments. In the drawings:

FIG. 1 is a schematic sectional view of a solar cell according to example embodiments.

FIGS. 2 and 3 are schematic sectional views illustrating a method of manufacturing the solar cell according to example embodiments.

FIGS. 4, 5(a), 5(b), and 6(a) to 6(h) are schematic sectional views of solar cells according to example embodiments.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted. In the drawing, parts having no relationship with the explanation are omitted for clarity

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

A solar cell and a manufacturing method thereof according to example embodiments are described in detail with reference to FIGS. 1 to 3.

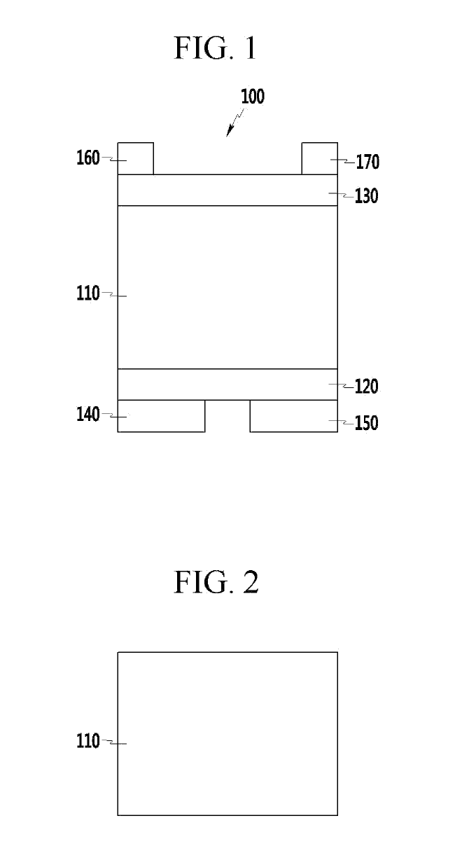

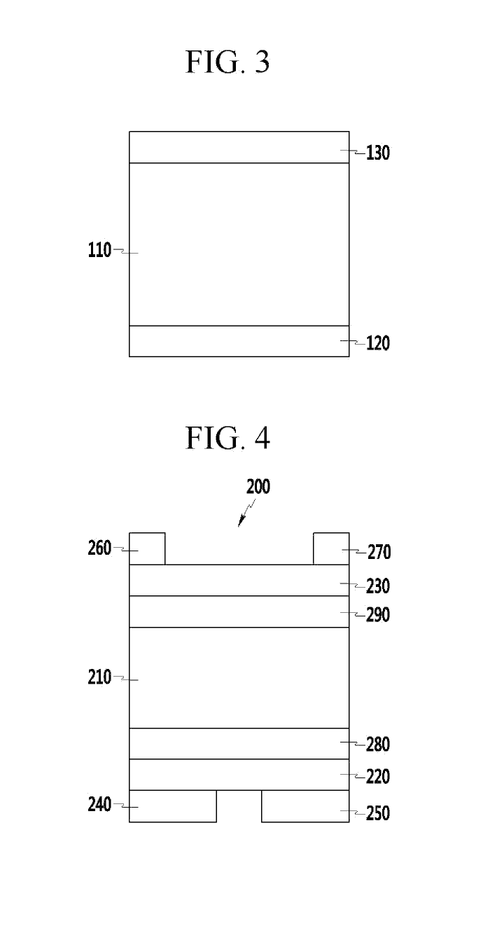

FIG. 1 is a schematic sectional view of a solar cell according to example embodiments, and FIGS. 2 and 3 are schematic sectional views illustrating a method of manufacturing the solar cell according to example embodiments.

A solar cell 100 according to example embodiments includes a transparent supporting base substrate 110, a lower photoelectric layer 120 and an upper photoelectric layer 130 that are deposited on lower and upper surfaces of the supporting substrate 110, respectively, and a plurality of terminals 140, 150, 160 and 170 connected to the lower and upper photoelectric layers 120 and 130.

The base substrate 110 may include an insulator electrically separating the lower photoelectric layer 120 and the upper photoelectric layer 130. The base substrate 110 may include a transparent substrate having a degree of strength, for example, glass, quartz, or plastic substrate so that the lower and upper photoelectric layers 120 and 130 may be deposited on the lower and upper surfaces of the base substrate 110 in forms of thin films. The thickness of the base substrate 110 may be about 50 microns (μm) to dozens of centimeters, but example embodiments are not limited thereto. If the base substrate 110 is a plastic, the base substrate 110 may include at least one of polyester, polyethylene, polyethersulfone (PES), polyamide, and polyimide, but example embodiments are not limited thereto.

The lower and upper photoelectric layers 120 and 130 may generate electricity upon receipt of light, and may have different energy bandgaps. For example, the bandgap of the upper photoelectric layer 130 may be greater than that of the lower photoelectric layer 120, and the difference in the bandgap between the lower photoelectric layer 120 and the upper photoelectric layer 130 may be about 0.3 to about 0.8 eV. If the bandgap difference between the photoelectric layers 120 and 130 is lower than 0.3 eV or greater than 0.8 eV, an available wavelength range of light may decrease or an output voltage may be less (and/or an output voltage may not be optimized), thereby reducing the efficiency of power generation. The bandgap of the lower photoelectric layer 120 may be about 0.4 eV to about 1.5 eV, and/or 0.5 eV to about 1.5 eV, while the bandgap of the upper photoelectric layer 130 may be about 1.0 eV to about 2.5 eV and/or about 1.0 eV to about 2.3 eV.

Examples of materials for the photoelectric layers 120 and 130 include various polymers and semiconductors that may be deposited in thin films, such as Si, Ge, Cu—In—Ga—Se (CIGS), CdTe, GaSb, InAs, PbS, GaP, ZnTe, CdS, AlP, and/or GaAs, but example embodiments are not limited thereto. Polycrystalline or single-crystalline silicon (Si) may have a bandgap of about 1.1 eV to about 1.2 eV, while amorphous silicon may have a higher bandgap of about 1.6 eV to about 1.7 eV. Germanium (Ge) may have a bandgap of about 0.6 eV to about 0.7 eV, and CdTe and GaAs may have a bandgap of about 1.4 eV to about 1.5 eV. GaSb may have a bandgap of about 0.7 eV, and InAs and PbS may have a bandgap of about 0.4 eV. GaP and ZnTe may have bandgap of about 2.2 eV to about 2.3 eV, and CdS and AlP may have bandgap of about 2.4 eV to about 2.5 eV. CIGS may have a bandgap of about 1.0 to about 1.7 eV depending on the composition ratio of In and Ga. A CIGS that contains mainly In but substantially no Ga, i.e., that contains Cu—In—Se as main ingredients (hereinafter referred to as “CIS”) may have a bandgap of about 1.0 eV. On the contrary, a CIGS that contains mainly Ga but substantially no In, i.e., that contains Cu—Ga—Se as main ingredients (hereinafter referred to as “CGS”) may have a bandgap about 1.7 eV. Polymers are known to have bandgaps of equal to or greater than about 1.7 eV.

The above-described materials are classified into three groups according to the degree of the bandgap. The first group has a bandgap of about 1.0 eV to about 1.2 eV and may include crystalline silicon and CIS (Cu—In—Se), and the second group has a bandgap equal to or greater than about 1.4 eV and may include amorphous silicon, CGS, CdTe, GaAs, GaP, ZnTe, CdS, AlP, and polymer. The last group has a bandgap equal to or lower than about 0.7 eV and may include Ge, GaSb, InAs, and PbS.

Among the three groups, the second group may be used mainly for the upper photoelectric layer 130, while the last group mainly for the lower photoelectric layer 120. The first group may be used for either the lower photoelectric layer 120 or the upper photoelectric layer 130 as the case may be. However, the usage is not limited thereto, and each of the groups may be used either the lower photoelectric layer 120 or the upper photoelectric layer 130 depending on the relative degree of the bandgap.

For example, when crystalline silicon and CIS in the first group is used for the upper photoelectric layer 130, Ge in the last group may be used for the lower photoelectric layer 120. On the contrary, when crystalline silicon and CIS in the first group is used for the lower photoelectric layer 120, amorphous silicon, CGS, CdTe, GaAs, GaP, ZnTe, CdS, AlP, and/or polymer may be used for the upper photoelectric layer 130. In this case, amorphous silicon and CGS that have bandgaps of about 1.6 eV to about 1.8 eV may give higher efficiency than CdTe and GaAs that have relatively low bandgaps in the second group.

The lower and upper photoelectric layers 120 and 130 may be formed by thin film deposition, for example, chemical deposition such as chemical vapor deposition (CVD) or physical deposition such as sputtering. Each of the photoelectric layers 120 and 130 may be about 50 nm to about 100 μm. However, example embodiments are not limited thereto.

The plurality of terminals 140, 150, 160 and 170 include a pair of lower terminals 140 and 150 disposed under the lower photoelectric layer 120 and a pair of lower terminals 160 and 170 disposed on the upper photoelectric layer 130. Therefore, the current flowing in each of the photoelectric layers 120 and 130 flows outward through respective terminals 140 and 150 or 160 and 170. That is, the current in the lower photoelectric layer 120 flows outward through the lower terminals 140 and 150, while that in the upper photoelectric layer 130 through the upper terminals 160 and 170. However, since the lower photoelectric layer 120 and the upper photoelectric layer 130 are electrically isolated from each other, the current from the lower photoelectric layer 120 may not pass through the upper terminals 160 and 170, and the current from the upper photoelectric layer 130 may not pass through the lower terminals 140 and 150.

Each of the terminals 140, 150, 160 and 170 may include low-resistivity metal such as copper and silver, and may have a thickness of about 500 nm to about 2 μm. The lower terminals 140 and 150 may be as wide as possible in order to reduce outward light leakage, while the upper terminals 160 and 170 may be as narrow as possible in order to reduce the blocking of the light heading for the photoelectric layers 120 and 130. For example, the width of each of the upper terminals 160 and 170 may be about 100 nm to about 1.5 μm.

According to example embodiments, a method of manufacturing the solar cell 100 is described with reference to FIG. 2. Referring to FIG. 2, a supporting base substrate 110 including at least one of transparent glass, quartz, and plastic is first prepared.

Thereafter, referring to FIG. 3, a lower photoelectric layer 120 and an upper photoelectric layer 130 are deposited on the base substrate 110 by thin film deposition, for example, one of CVD, or sputtering.

Finally, lower terminals 140 and 150 and upper terminals 160 and 170 are formed on the lower photoelectric layer 120 and the upper photoelectric layer 130, respectively, as shown in FIG. 1.

In the above-described structure of the solar cell 100, the magnitude of the current generated by the lower photoelectric layer 120 may be different from the magnitude of the current generated by the upper photoelectric layer 130. In this case, if the upper photoelectric layer 130 and the lower photoelectric layer 120 are electrically connected to each other, a net current of the solar cell may be determined by a lower one of the currents generated by the upper photoelectric layer 130 and the lower photoelectric layer 120. Therefore, an excess amount of the current generated by one of the photoelectric layers 120 and 130 may not be utilized, which may reduce the efficiency of the solar cell. However, solar cells according to example embodiments electrically separate the upper photoelectric layer 130 and the lower photoelectric layer 120 to collect the currents having different magnitudes generated by the upper photoelectric layer 130 and the lower photoelectric layer 120 to be used without current loss, thereby increasing the efficiency.

Furthermore, since the lower and upper photoelectric layers 120 and 130 are formed as thin films under and on the transparent supporting base substrate 110, the manufacturing process may be simple and the manufacturing cost may be reduced. In particular, when using glass or plastic for the base substrate 110, the manufacturing cost may be much reduced compared with a case that one of the lower and upper photoelectric layers 120 and 130 is a single crystalline silicon substrate.

Next, a solar cell according to example embodiments is described with reference to FIG. 4.

FIG. 4 is a schematic sectional view of a solar cell according to example embodiments.

Referring to FIG. 4, a solar cell 200 includes a supporting base substrate 210, a lower photoelectric layer 220, an upper photoelectric layer 230, lower terminals 240 and 250, and upper terminals 260 and 270, like the solar cell 100 shown in FIG. 1. However, unlike the solar cell 100 shown in FIG. 1, the solar cell 200 further includes lower and upper passivation layers 280 and 290 disposed between the base substrate 210 and the lower and upper photoelectric layers 220 and 230, respectively.

The passivation layers 280 and 290 may limit (and/or prevent) defects due to the direct contact between the base substrate 210 and the photoelectric layers 220 and 230, for example, poor adhesion therebetween or contamination of the photoelectric layers 220 and 230. The passivation layers 280 and 290 may include a dielectric material such as an oxide layer or a nitride layer having a thickness of about 1 nm to about 500 nm, or may include a semiconductor material such as an amorphous silicon layer having a thickness of about 0.5 nm to about 500 nm. For example, the passivation layers 280 and 290 may each independently include at least one of silicon oxide, silicon nitride, silicon oxynitride, and aluminum oxide. The passivation layers 280 and 290 include the same or different materials.

One of the lower and upper passivation layers 280 and 290 may be omitted.

Other portions of the solar cell 200 may be similar to corresponding portions shown in FIG. 1, and thus the detailed description thereof is omitted.

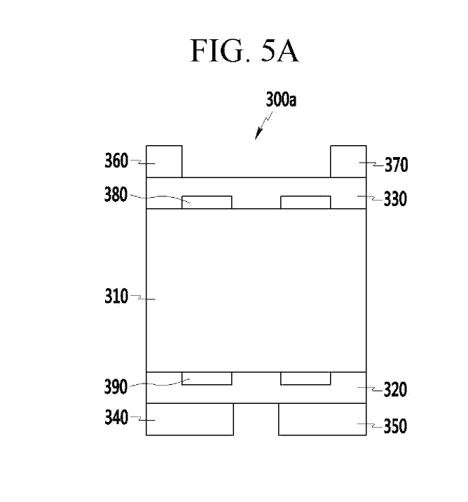

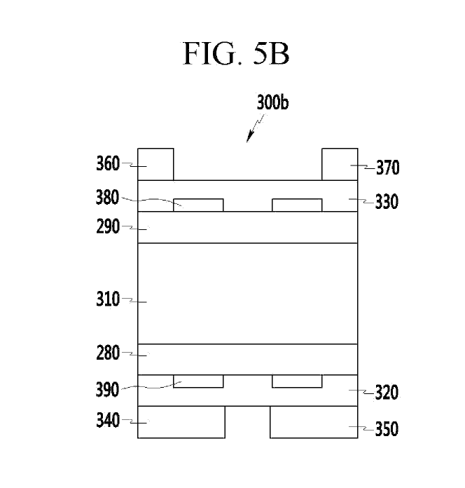

Next, a solar cell according to example embodiments is described in detail with reference to FIGS. 5(a) and 5(b).

FIG. 5(a) is a schematic sectional view of a solar cell according to example embodiments.

Referring to FIG. 5(a), a solar cell 300a includes a supporting base substrate 310, a lower photoelectric layer 320, an upper photoelectric layer 330, lower terminals 340 and 350, and upper terminals 360 and 370, like the solar cell 100 shown in FIG. 1. However, unlike the solar cell 100 shown in FIG. 1, the solar cell 300a further includes lower and upper wavelength conversion members 380 and 390 disposed between the base substrate 310 and the lower and upper photoelectric layers 320 and 330, respectively.

The wavelength conversion members 380 and 390 may change the wavelength of incident light, for example, may convert light that may not be absorbed by the photoelectric layers 320 and 330 into light that may be absorbed by the photoelectric layers 320 and 330. The wavelength conversion members 380 and 390 may be formed by forming patterns on surfaces of the base substrate 310, or by depositing a metal such as gold or aluminum in forms of nanoparticles on the base substrate 310 to generate plasmons. Conversion of a desired range of wavelength into a wavelength range that may be absorbed by the photoelectric layers 320 and 330 may be realized by adjusting the size and the pitch of the wavelength conversion members 380 and 390.

The wavelength conversion members 380 and 390 may include at least one of rare earth ions (e.g., Er+3, Tb+3, Tm+3, and Yb+3), transition metal ions (Zn, Pb, Ti, and Cd+), and nanocrystals (e.g., silicon quantum dots). However, example embodiments are not limited thereto.

One of the wavelength conversion members 380 and 390 may be omitted.

The solar cell 300a may further include the passivation layers 280 and 290 shown in FIG. 4.

Referring to FIG. 5(b), a solar cell 300b according to example embodiments may include each feature of the solar cell 300a in FIG. 5(a) and further include the passivation layers 280 and 290 shown in FIG. 4. In the solar cell 300b illustrated in FIG. 5(b), one of the wavelength conversion members 380 and 390 may be omitted, and/or one of the passivation layers 280 and 290 may be omitted.

As described above, the solar cell 300 utilizes the wavelength conversion members 380 and 390 to make use of light with almost all ranges of wavelength in power generation, thereby increasing power generation efficiency.

Other portions of the solar cell 300 may be similar to corresponding portions shown in FIG. 1, and thus the detailed description thereof is omitted.

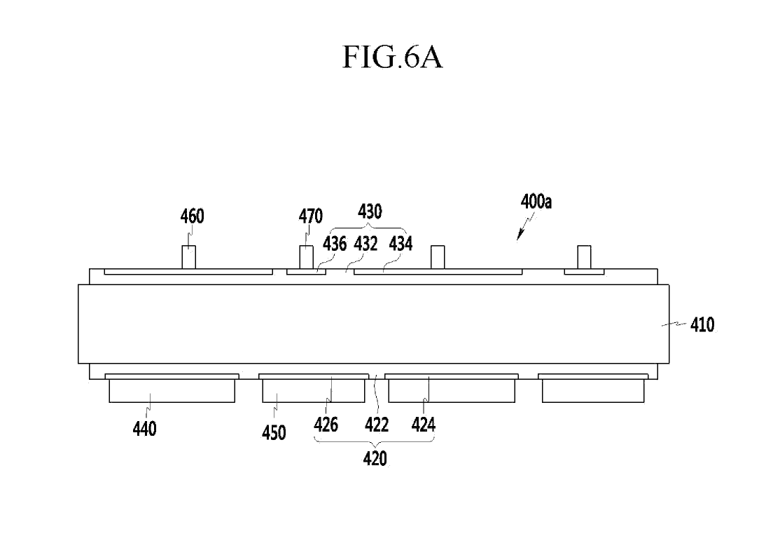

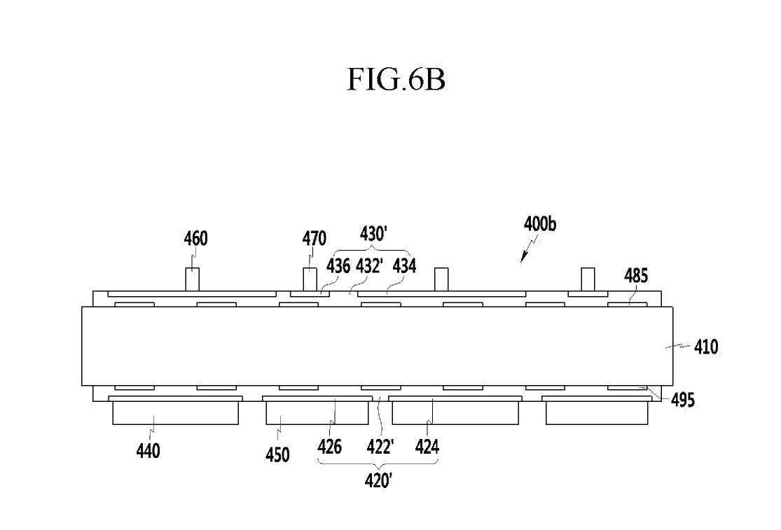

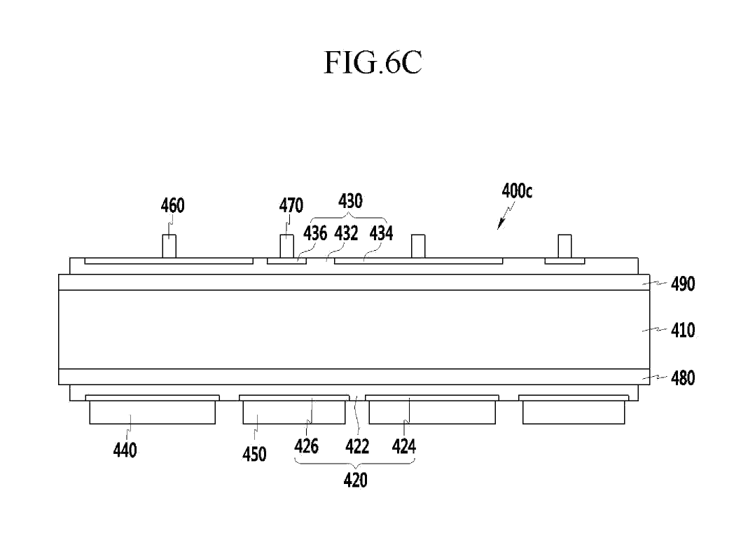

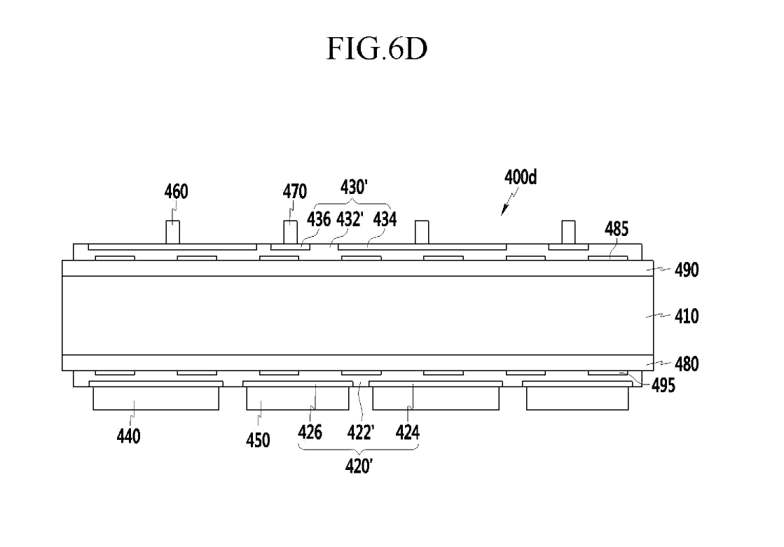

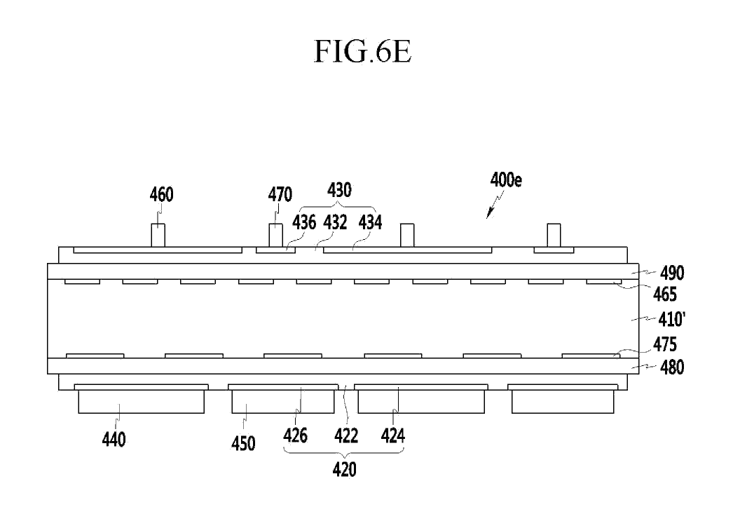

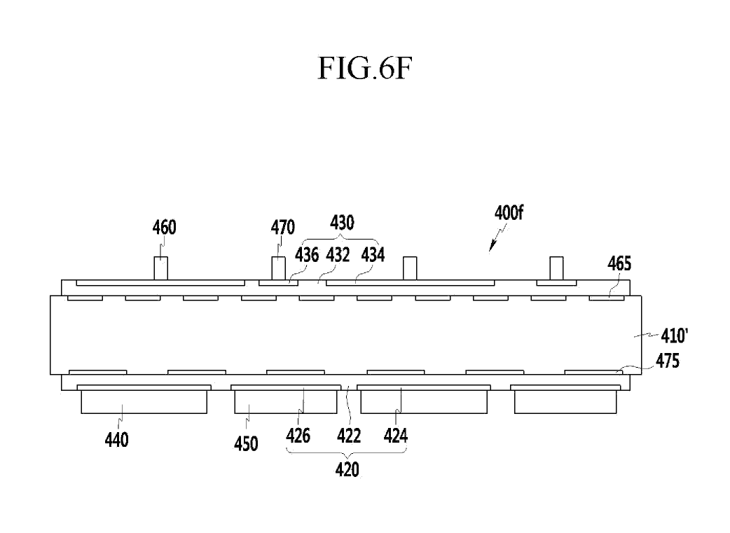

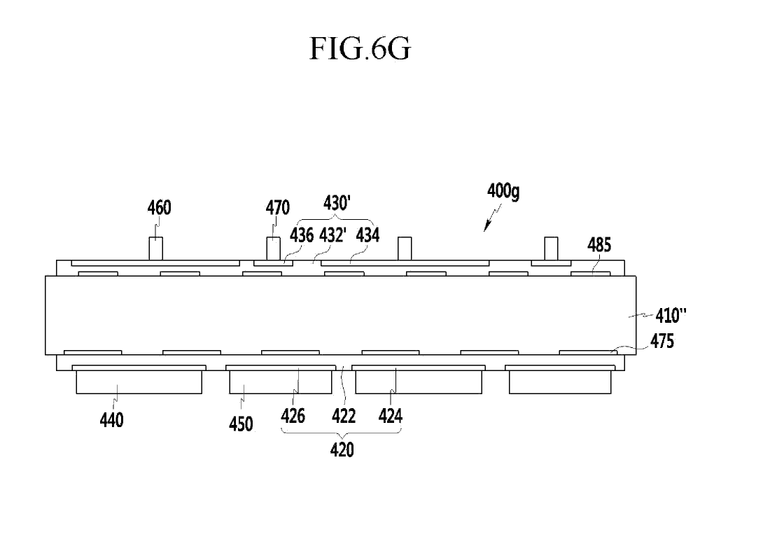

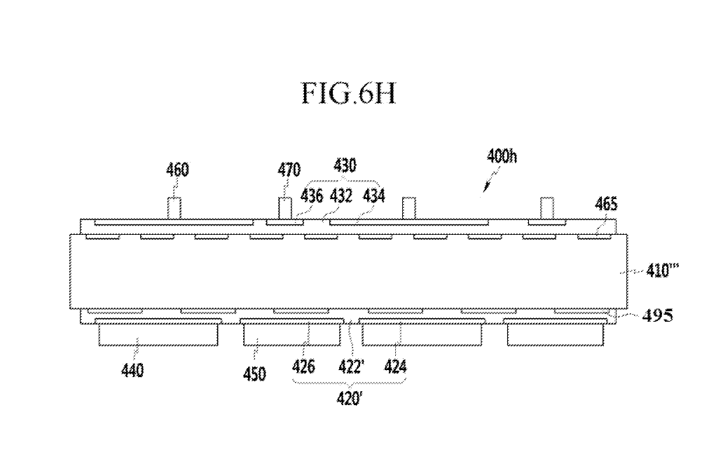

Next, solar cells according to example embodiments are described in detail with reference to FIGS. 6(a) to 6(h).

FIG. 6(a) is a schematic sectional view of a solar cell 400a according to example embodiments.

Referring to FIG. 6(a), a solar cell 400a includes a transparent supporting base substrate 410, a lower photoelectric layer 420, an upper photoelectric layer 430, lower terminals 440 and 450, and upper terminals 460 and 470, like the solar cell 100 shown in FIG. 1.

The lower photoelectric layer 420 includes a low-concentration impurity region 422 and a plurality of high-concentration impurity regions 424 and 426 that are disposed in the low-concentration impurity region 422 near a top surface and have impurity concentrations higher than the low-concentration impurity region 422. Similarly, the upper photoelectric layer 430 includes a low-concentration impurity region 432 and a plurality of high-concentration impurity regions 434 and 436 that are disposed in the low-concentration impurity region 432 near a top surface and have impurity concentrations higher than the low-concentration impurity region 432.

The low-concentration impurity regions 422 and 432 may include P-type or N-type impurity, and the low-concentration impurity region 422 of the lower photoelectric layer 420 and the low-concentration impurity region 432 of the upper photoelectric layer 430 may have opposite conductivities.

The high-concentration impurity regions 424, 426, 434 and 436 may be spaced apart from one another, and may be connected to corresponding lower and upper terminals 440, 450, 460 and 470. Adjacent high-concentration impurity regions 424, 426, 434 and 436 may have opposite conductivities.

The high-concentration impurity regions 434 and 436 of the upper photoelectric layer 430 may be either large or small, and the large high-concentration impurity regions 434 and the small high-concentration impurity regions 436 may be alternately arranged. The large high-concentration impurity regions 434 may have a conductivity opposite to a conductivity of the small high-concentration impurity regions 436 and the low-concentration impurity region 432. For example, when the low-concentration impurity region 432 includes P-type impurity of low concentration, the small high-concentration impurity region 436 may include P-type impurity of high concentration while the large high-concentration impurity region 434 may include N-type impurity of high concentration. On the contrary, when the low-concentration impurity region 432 includes N-type impurity of low concentration, the small high-concentration impurity region 436 may include N-type impurity of high concentration while the large high-concentration impurity region 434 may include P-type impurity of high concentration.

Like the upper photoelectric layer 430, the high-concentration impurity regions 424 and 426 of the lower photoelectric layer 420 may be either large or small, and the large high-concentration impurity regions 424 and the small high-concentration impurity regions 426 may be alternately arranged. However, the size difference between the large high-concentration impurity region 424 and the small high-concentration impurity regions 426 may be insignificant compared with that in the upper photoelectric layer 430.

The impurities in the photoelectric layers 420 and 430 may be introduced by ion implantation and/or a diffusion process.

FIG. 6(b) is a schematic illustration of a solar cell 400b according to example embodiments. The solar cell 400b illustrated in FIG. 6(b) is like the solar cell 400a in FIG. 6(a), except the solar cell 400b further includes wavelength conversion members 485 and 495 in the low-concentration impurity regions 432′ and 422′ of the upper photoelectric layer 430′ and the lower photoelectric layer 420′ respectively. The materials for the wavelength conversion members 485 and 495 may be the same as the materials of the wavelength conversion members 380 and 390 shown in FIGS. 5(a) and 5(b). One of the wavelength conversion members 485 and 495 may be omitted.

FIG. 6(c) a schematic illustration of a solar cell 400c according to example embodiments. The solar cell 400c illustrated in FIG. 6(c) is like the solar cell 400a in FIG. 6(a), except the solar cell 400c further includes passivation layers 490 and 480 between the base substrate 410 and the upper 430 and lower 420 photoelectric layers. The passivation layers 490 and 480 may contain the same materials as the passivation layers 290 and 280 discussed above with reference to FIG. 4. One of the passivation layers 485 and 495 may be omitted.

FIG. 6(d) a schematic illustration of a solar cell 400d according to example embodiments. The solar cell 400d illustrated in FIG. 6(d) is like the solar cell 400a in FIG. 6(a), except the solar cell 400d further includes passivation layers 490 and 480 between the base substrate 410 and the upper 430 and lower 420 photoelectric layers and the solar cell 400d further includes wavelength conversion members 485 and 495 in the low-concentration impurity regions 432′ and 422′ of the upper photoelectric layer 430′ and the lower photoelectric layer 420′ respectively.

FIG. 6(e) a schematic illustration of a solar cell 400e according to example embodiments. The solar cell 400e illustrated in FIG. 6(e) is like the solar cell 400c in FIG. 6(c), except the solar cell 400e further includes wavelength conversion members 465 and 475 in the base substrate 410′. The wavelength conversion members 465 and 475 may contain the same materials as the wavelength conversion members 485 and 495 described above. One of the wavelength conversion members 465 and 475 may be omitted. One of the passivation layers 490 and 480 may be omitted.

FIG. 6(f) is a schematic illustration of a solar cell 400f according to example embodiments. The solar cell 400f is like the solar cell 400e, except the passivation members 490 and 480 are omitted.

FIG. 6(g) is a schematic illustration of a solar 400g according to example embodiments. The solar cell 400g is like the solar cell 400a shown in FIG. 6(a), except the solar cell 400g further includes wavelength conversion members 485 in the upper photoelectric layer 430′ and wavelength conversion members 475 in the base substrate 410″.

FIG. 6(h) is a schematic illustration of a solar 400h according to example embodiments. The solar cell 400h is like the solar cell 400a shown in FIG. 6(a), except the solar cell 400h further includes wavelength conversion members 495 in the lower photoelectric layer 420′ and wavelength conversion members 465 in the base substrate 410′″.

The solar cells 400g and 400h illustrated in FIGS. 6(g) and 6(h) may further include at least one of the passivation layers 490 and 480 between the base substrate 410″ or 410′″ and the upper photoelectric layer 430 or 430′ and/or lower photoelectric layer 420 or 420′, as described above.

Although FIGS. 1 to 4, 5(a), 5(b), and 6(a) to 6(h) illustrate schematic sectional views of solar cells according to example embodiments, example embodiments are not limited thereto. One having ordinary skill in the art would appreciate that one or more of the foregoing solar cells according to example embodiments may be electrically connected in series, parallel, and series-parallel arrangements in order to form a solar cell module configured to generate desired current, voltage, and/or power characteristics.

According to example embodiments, since the photoelectric layers having different energy bandgaps are electrically separated, the currents generated from the photoelectric layers may be collected to be used in a whole, thereby increasing the efficiency of power generation. In addition, the photoelectric layers are formed in forms of thin films under and on the transparent supporting base substrate, the manufacturing process may be simple and the manufacturing cost may be reduced.

While some example embodiments have been particularly shown and described, it will be understood by one of ordinary skill in the art that variations in form and detail may be made therein without departing from the spirit and scope of the claims.

What is claimed is:

1. A solar cell comprising:
a transparent base substrate having a first surface and a second surface opposite the first surface;
a first photoelectric layer having a thin film shape on the first surface of the base substrate; and
a second photoelectric layer having a thin film shape on the second surface of the base substrate,
the second photoelectric layer having a bandgap different than a bandgap of the first photoelectric layer.

2. The solar cell of claim 1, wherein
the first surface is under the second surface, and
the bandgap of the first photoelectric layer is smaller than the bandgap of the second photoelectric layer.

3. The solar cell of claim 2, further comprising:
first and second terminals connected to the first photoelectric layer,
the first photoelectric layer being between the base substrate and the first and second terminals; and
third and fourth terminals connected to the second photoelectric layer,
the second photoelectric layer being between the base substrate and the third and fourth terminals.

4. The solar cell of claim 3, wherein
the first photoelectric layer includes first and second impurity regions connected to the first and second terminals, respectively,
the first and second impurity regions having opposite conductivities, and
the second photoelectric layer includes third and fourth impurity regions connected to the third and fourth terminals, respectively,
the third and fourth impurity regions having opposite conductivities.

5. The solar cell of claim 3, further comprising:
a passivation layer between the base substrate and the first photoelectric layer.

6. The solar cell of claim 1, further comprising:
a wavelength conversion member between the base substrate and the first photoelectric layer,
wherein the wavelength conversion member is configured to change a wavelength of incident light.

7. The solar cell of claim 6, wherein the wavelength conversion member is a pattern on the base substrate.

8. The solar cell of claim 6, wherein the wavelength conversion member includes nanoparticles.

9. The solar cell of claim 1, wherein the base substrate includes an insulator.

10. The solar cell of claim 9, wherein the base substrate includes at least one of glass, quartz, and plastic.

11. The solar cell of claim 1, wherein the base substrate has a thickness from about 50 microns to about 10 centimeters.

12. A method of manufacturing a solar cell, the method comprising:
forming a first photoelectric layer by thin film deposition on a first surface of a transparent insulating base substrate;
forming a second photoelectric layer by thin film deposition on a second surface of the base substrate,
the second photoelectric layer having a bandgap different from a bandgap of the first photoelectric layer,
the first surface and the second surface of the base substrate being opposite to each other;
forming a first electrode on the first photoelectric layer opposite the base substrate; and
forming a second electrode on the second photoelectric layer opposite the base substrate.

13. The method of claim 12, wherein
the first surface is under the second surface, and
the bandgap of the first photoelectric layer is less than the bandgap of the second photoelectric layer.

14. The method of claim 13, further comprising:
forming a plurality of impurity regions by implanting impurities in the first and second photoelectric layers.

15. The method of claim 13, further comprising:
forming a passivation layer between the base substrate and the first photoelectric layer.

16. The method of claim 12, further comprising:
forming a wavelength conversion member between the base substrate and the first photoelectric layer,
the wavelength conversion member configured to change a wavelength of incident light.

17. The method of claim 16, wherein the forming the wavelength conversion member comprises:
forming a pattern on the base substrate.

18. The method of claim 16, wherein the forming the wavelength conversion member comprises:
forming nanoparticles on the base substrate.

19. The method of claim 12, wherein the base substrate includes at least one of glass, quartz, and plastic.

20. The method of claim 12, wherein the base substrate has a thickness from about 50 microns to about 10 centimeters.

21. The method of claim 12, wherein the thin film deposition includes one of chemical deposition and physical deposition.
